(19) United States
(12) Patent Application Publication
(10) Pub. No.: US 2018/0297893 A1
(43) Pub. Date: Oct. 18, 2018

(54) SEMICONDUCTOR NANOCRYSTAL FILM

(71) Applicant: Korea Advanced Institute of Science and Technology, Daejeon (KR)

(72) Inventors: Byeong-Soo BAE, Daejeon (KR); Young-Woo LIM, Daejeon (KR); Hyunhwan LEE, Daejeon (KR)

(21) Appl. No.: 15/945,841

(22) Filed: Apr. 5, 2018

(30) Foreign Application Priority Data
Apr. 18, 2017 (KR) 10-2017-0049919

(51) Int. Cl. C03C 25/1095; H01L 31/0216; H01L 33/50; C03C 25/47; C03C 25/42; C03C 25/40; C03C 25/285; C03C 25/36; C03C 25/48

(52) U.S. Cl. CPC C03C 25/1095; H01L 31/02162; H01L 33/502; H01L 33/505; C03C 25/48; C03C 25/42; C03C 25/40; C03C 25/285; C03C 25/36; C03C 25/47

(57) ABSTRACT

A semiconductor nanocrystal film according to an exemplary embodiment of the present invention includes a glass cloth including a glass fiber having a composition of E glass, S glass, T glass, or E-CR glass, a polymer matrix impregnated in the glass cloth, and a semiconductor nanocrystal dispersed in the polymer matrix, and thus may exhibit uniform light emitting distribution, a low coefficient of thermal expansion, and excellent mechanical strength.

### CROSS-REFERENCE TO RELATED APPLICATION

This application claims priority to and the benefit of Korean Patent Application No. 10-2017-0049919 filed in the Korean Intellectual Property Office on Apr. 18, 2017, the entire contents of which are incorporated herein by reference.

### BACKGROUND OF THE INVENTION

### (a) Field of the Invention

The present invention relates to a semiconductor nanocrystal film.

### (b) Description of the Related Art

A semiconductor nanocrystal, which is also called quantum dot, is a nanometer-sized semiconductor crystal. When a radius of the semiconductor nanocrystal is adjusted, it may selectively emit light having a desirable wavelength throughout the whole range of visible rays. Thereby, the semiconductor nanocrystal is drawing a lot of attention as a next generation color conversion device of a photoelectric device, a display, and a light.

The semiconductor nanocrystal may be applied for a light emitting diode and the like through three ways, and of these, an on-chip type has a problem that the semiconductor nanocrystal is easily damaged by heat generated from the light emitting diode and the like, and an edge-type has problems in that the producible size is limited and it is difficult to provide a flexible light emitting diode, so application of the semiconductor nanocrystal to a light emitting diode as a film-type is being actively researched.

As the method of applying the semiconductor nanocrystal to a light emitting diode and the like as a film type, a method has been suggested to include dispersing a semiconductor nanocrystal in a curable transparent polymer resin, shaping the same as desirable, and curing the resin. Generally, the resin-cured product in which the semiconductor nanocrystal is dispersed is formed in a film or a sheet. In addition, a method is also suggested to include dispersing a semiconductor nanocrystal in a curable liquid transparent polymer resin and coating the same on a transparent substrate according to a spin coating, a drop casting, or a doctor blade method. Generally, as the transparent polymer for dispersing the semiconductor nanocrystal, (meth)acryl-based, epoxy-based, urethane-based, polyester-based, silicon-based, and siloxane-based resins may be used as they are easily cured and handled.

Recently, for enhancing light extraction efficiency of the semiconductor nanocrystal film and providing uniform light emission through a whole area, it has been suggested to further laminate a light diffusion film on the light semiconductor nanocrystal film, or to add an inorganic oxide particle including silica, alumina, titania, and the like or a polymer particle as a scattering agent into the film.

However, the method of further laminating a light diffusing film has problems that the process becomes complicated due to the additional process, and the cost is increased, and the method of adding a scattering particle has drawbacks in that the process of forming particles is complicated, and it is difficult to provide uniform light emitting distribution due to the particle agglomeration.

Further, as the semiconductor nanocrystal has high thermal conductivity, it emits a large amount of heat when the wavelength of light is converted by the semiconductor nanocrystal. Thus, a semiconductor nanocrystal film including the polymer resin having a relatively high coefficient of thermal expansion is easily deformed, so the luminance may be deteriorated.

### SUMMARY OF THE INVENTION

An embodiment of the present invention provides a semiconductor nanocrystal film in which a semiconductor nanocrystal is uniformly distributed in a polymer matrix without an agglomeration phenomenon.

An embodiment of the present invention provides a semiconductor nanocrystal film showing uniform light emission distribution when light enters.

An embodiment of the present invention provides a semiconductor nanocrystal film having a very low coefficient of thermal expansion and excellent mechanical strength.

An embodiment of the present invention provides a semiconductor nanocrystal film having increased quantum efficiency and high luminance.

A semiconductor nanocrystal film according to an exemplary embodiment of the present invention includes a glass cloth including a glass fiber having a composition of E glass, S glass, T glass, or E-CR glass, a polymer matrix impregnated in the glass cloth, and a semiconductor nanocrystal dispersed in the polymer matrix.

Herein, the semiconductor nanocrystal film may have a film shape, and the semiconductor nanocrystal film may have a coefficient of thermal expansion of less than or equal to 50 ppm/° C.

The polymer matrix may include a (meth)acryl-based resin, an epoxy-based resin, a urethane-based resin, a polyester-based resin, a silicone-based resin, a siloxane-based resin, or a combination thereof.

The glass cloth may be a glass woven fabric, a glass non-woven fabric, or a mixture thereof.

The glass cloth may further include a metal layer formed on the surface.

A refractive index difference between the polymer matrix and the glass cloth at a wavelength of 632.8 nm may be greater than or equal to about 0.01.

The semiconductor nanocrystal may be selected from a Group II-VI compound, a Group II-V compound, a Group III-VI compound, a Group III-V compound, a Group IV-VI compound, a Group II-III-VI compound, a Group II-IV-VI compound, a Group II-IV-V compound, a Group IV compound, an alloy thereof, and a combination thereof.

It may be used as a color conversion device for a photoelectric device, a display, or a light.

As the semiconductor nanocrystal film according to an embodiment of the present invention includes a glass cloth, it may include a semiconductor nanocrystal which is uniformly distributed in the polymer matrix without agglomeration, unlike the conventional film with scattering particles added thereto. Thereby, when light enters into the semiconductor nanocrystal film, it may show uniform light emission distribution. In addition, as the semiconductor nanocrystal film includes a glass cloth, it may have a very low coefficient of thermal expansion and excellent mechanical strength. In addition, the semiconductor nanocrystal film may have enhanced quantum efficiency and high luminance due to the scattering occurring at the interface between the polymer matrix and the glass cloth.

### BRIEF DESCRIPTION OF THE DRAWING

FIG. 1 is a schematic cross-sectional view of a semiconductor nanocrystal film according to an embodiment of the present invention.

### DETAILED DESCRIPTION

Hereinafter, exemplary embodiments of the present invention will be described in detail with reference to the accompanying drawings so that a skilled person in the technical field to which the present invention pertains may easily carry out the exemplary embodiments. As those skilled in the art would realize, the described embodiments may be modified in various different ways, all without departing from the spirit or scope of the present invention. Parts that are irrelevant to the description will be omitted to clearly describe the present invention, and the same or similar constituent elements will be designated by the same reference numerals throughout the specification. In addition, detailed description of widely known technologies will be omitted.

In addition, throughout the specification, unless explicitly described to the contrary, the word “comprise” and variations such as “comprises” or “comprising” will be understood to imply the inclusion of stated elements but not the exclusion of any other elements.

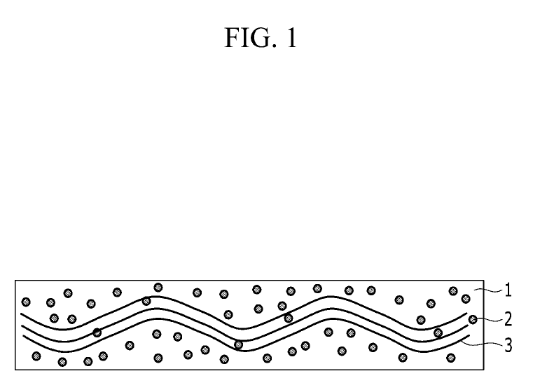

Hereinafter, a semiconductor nanocrystal film according to a specific embodiment is described referring to FIG. 1.

According to an embodiment, a semiconductor nanocrystal film includes a glass cloth 3, a polymer matrix 1 impregnated in the glass cloth 3, and a semiconductor nanocrystal 2 dispersed in the polymer matrix 1.

The glass cloth 3 is one of which glass fiber is formed in a film, and means a glass woven fabric which is woven with glass fiber or a glass non-woven fabric which is an entanglement of glass fiber. The film with an inorganic oxide particle or a polymer particle added as a scattering agent for enhancing light extraction efficiency of the semiconductor nanocrystal film has problems in that the process of forming a scattering particle is complicated, and the scattering particle is fragile during the process of manufacturing the film, causing deterioration of process stability; and the scattering particle is easily agglomerated in the film and inhibits the dispersion of the semiconductor nanocrystal 2, causing difficulty in providing uniform light emission distribution. However, the glass cloth 3 does not cause agglomeration in the semiconductor nanocrystal film and allows the semiconductor nanocrystal 2 to be uniformly dispersed in the polymer matrix 1, so as to ensure uniform light diffusion of the semiconductor nanocrystal film.

In addition, the glass cloth 3 remarkably decreases the coefficient of thermal expansion of the semiconductor nanocrystal film and significantly enhances the mechanical strength, compared to the case of using the conventional scattering agent. Specifically, the semiconductor nanocrystal film including the glass cloth 3 may have a coefficient of thermal expansion of less than or equal to about 50 ppm/° C., about 1 to about 40 ppm/° C., about 5 to about 30 ppm/° C., or about 10 to about 20 ppm/° C.

Thereby, the semiconductor nanocrystal film is not easily deformed or damaged under a severe environment so it can be used for a long time, and it may be widely applied for the various fields such as a photoelectric device, a display, and a lighten.

The polymer matrix 1 is a polymer resin in which a composition including a curable resin or a polymerizable monomer is cured by heat and/or light. More specifically, it is a polymer resin of which a composition including the curable resin or a polymerizable monomer, and if required, a curing catalyst, a cross-linking agent, an initiator, or the like, is cured by heat and/or light.

As described later, as the refractive index difference between the polymer matrix 1 and the glass cloth 3 becomes higher, it may provide a semiconductor nanocrystal film with higher haze. Accordingly, as the polymer resin for the polymer matrix 1, an appropriate polymer resin may be selected according to the usage of the semiconductor nanocrystal film and properties required in the usage. For example, the polymer matrix 1 may include a transparent polymer resin, and specifically, a (meth)acryl-based resin, an epoxy-based resin, a urethane-based resin, a polyester-based resin, a silicone-based resin, a siloxane-based resin, or a combination thereof.

The semiconductor nanocrystal film includes a cured product (polymer matrix 1) impregnated in the glass cloth 3 as the composition is cured in a state that the composition for the polymer matrix 1 is impregnated in the glass cloth 3. In the present specification, the term ‘impregnated’ means that the composition for the polymer matrix 1 or the polymer matrix 1 is filled in the inner space of the glass cloth 3, or that the composition for the polymer matrix 1 or the polymer matrix 1 is covered on the surface of the glass cloth 3.

The glass cloth 3 is formed by shaping glass fiber into a film, and it may include a glass woven fabric which is woven with the glass fiber, a glass non-woven fabric which is an entanglement of the glass fiber, or a mixture thereof. The glass fiber for the glass cloth 3 may have a composition selected from a group consisting of E glass, C glass, A glass, S glass, D glass, T glass, NE glass, E-CR glass, quartz, a low dielectric constant (low-k) glass, and a high dielectric constant glass. More specifically, the glass fiber may have a composition of E glass, S glass, T glass, or E-CR glass having lower amounts of ionic impurities among the mentioned compositions.

The amount of the glass cloth 3 in the semiconductor nanocrystal film is not particularly limited. However, the semiconductor nanocrystal film may include the glass cloth 3 at about 20 to about 80 parts by volume based on 100 parts by volume of the polymer matrix 1, considering the mechanical property enforcing effects by the glass cloth 3 and the luminance enhancing effect by the light scattering.

The light having entered the semiconductor nanocrystal film or emitted from the semiconductor nanocrystal 2 is primarily scattered at the interface between the polymer matrix 1 and the glass cloth 3. Accordingly, as a refractive index difference between the polymer matrix 1 and the glass cloth 3 is higher, the light is increasingly refracted at the interface between the polymer matrix 1 and the glass cloth 3 to improve the light scattering effect, and resultantly it may express high color conversion efficiency and high luminance.

Specifically, when the refractive index difference between the polymer matrix 1 and the glass cloth 3 at a wavelength of 632.8 nm is greater than or equal to 0.01, the semiconductor nanocrystal film may exhibit haze of greater than or equal to 25%. In addition, when the refractive index difference between the polymer matrix 1 and the glass cloth 3 at a wavelength of 632.8 nm is greater than or equal to 0.03, the semiconductor nanocrystal film may exhibit haze of greater than or equal to 70%. The haze is a value representing a ratio of light scattered in directions other than a direct line with respect to the entire transmitted light. As the haze is higher, the luminance is higher.

Meanwhile, the glass cloth 3 may further include a metal layer on the surface thereof. It may show excellent much better light scattering effect and heat radiating effect when the metal layer is formed on the surface of the glass cloth 3. Specific examples of the metal layer may include a layer formed with at least one metal selected from a group consisting of Al, Ag, Au, Cu, Zn, and Ti.

The semiconductor nanocrystal 2 may be selected from a Group II-VI compound, a Group II-V compound, a Group III-VI compound, a Group III-V compound, a Group IV-VI compound, a Group II-III-VI compound, a Group II-IV-VI compound, a Group II-IV-V compound, a Group IV compound, an alloy thereof, and a combination thereof.

The Group II element may be Zn, Cd, Hg, or a combination thereof, the Group III element may be B, Al, Ga, In, Ti, or a combination thereof, the Group IV element may be C, Si, Ge, Sn, Pb, or a combination thereof, the Group V element may be N, P, As, Sb, Bi, or a combination thereof, and the Group VI element may be O, S, Se, Te, or a combination thereof.

The Group II-VI compound may be selected from a binary element compound of CdS, CdSe, CdTe, ZnS, ZnSe, ZnTe, ZnO, HgS, HgSe, HgTe, and the like, a ternary element compound of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, and the like, or a quaternary element compound of CdZnSeS, CdZnSeTe, CdZnSTe, CdHgSeS, CdHgSeTe, CdHgSTe, HgZnSeS, HgZnSeTe, HgZnSTe, and the like. The Group III-V compound may be selected from a binary element compound of GaN, GaP, GaAs, GaSb, AlN, AlP, AlAs, AlSb, InN, InP, InAs, InSb, and the like, a ternary element compound of GaNP, GaNAs, GaNSb, GaPAs, GaPSb, AlNP, AlNAs, AlNSb, AlPAs, AlPSb, InNP, InNAs, InNSb, InPAs, InPSb, GaAlNP, AlGaN, AlGaP, AlGaAs, AlGaSb, InGaN, InGaP, InGaAs, InGaSb, AlInN, AlInP, AlInAs, AlInSb, and the like, or a quaternary element compound of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and the like. The Group IV-VI compound may be selected from a binary element compound of SnS, SnSe, SnTe, PbS, PbSe, PbTe, and the like, a ternary element compound of SnSeS, SnSeTe, SnSTe, PbSeS, PbSeTe, PbSTe, SnPbS, SnPbSe, SnPbTe, and the like, or a quaternary element compound of SnPbSSe, SnPbSeTe, SnPbSTe, and the like. The Group IV compound may be selected from a single element compound of Si, Ge, and the like, or a binary element compound of SiC, SiGe, and the like.

As the semiconductor nanocrystal 2 is included at 0.01 to 10 parts by weight based on 100 parts by weight of the polymer matrix 1, it shows high color conversion efficiency.

A method of manufacturing the semiconductor nanocrystal film is not particularly limited. For example, the semiconductor nanocrystal film may be obtained by adding an appropriate amount of semiconductor nanocrystal 2 into a composition for a polymer matrix 1, uniformly mixing the same, and curing the composition in a state that the composition is impregnated into a glass cloth 3. The composition for the polymer matrix 1 may include, if required, a curing catalyst, a cross-linking agent, or an initiator together with the curable resin or the polymerizable monomer as described above. For another example, the semiconductor nanocrystal film may be obtained by adding and mixing the semiconductor nanocrystal 2 and the glass cloth 3 into the composition for a polymer matrix 1 and spreading the same to a desirable shape and curing the same.

Hereinafter, specific examples are illustrated to explain functions and effects in detail. However, the examples are simply exemplary of the present invention, and the present invention is not limited thereto.

### Example 1: Fabrication of Semiconductor Nanocrystal Film

A first silicone resin (OE6630A, manufactured by Dow Corning Corp.) and a second silicone resin (OE6630B, manufactured by Dow Corning Corp.) were mixed at a weight ratio of 1:4, and vapor was removed. A semiconductor nanocrystal dispersed in chloroform (Cd based core-shell structure, Nanodot-HE-620, manufactured by Ecoflux) was added into the obtained polymer resin mixture and uniformly mixed. In this case, the semiconductor nanocrystal was added at 1 part by weight based on 100 parts by weight of the polymer resin.

Meanwhile, two sheets of glass fabric woven with glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric.

It was then cured at 150° C. for 2 hours to prepare a semiconductor nanocrystal film. After the curing, the obtained semiconductor nanocrystal film was delaminated from the glass substrate.

### Example 2: Fabrication of Semiconductor Nanocrystal Film

A first silicone resin (SYLGARD 184A, manufactured by Dow Corning Corp.) and a second silicone resin (SYLGARD 184B, manufactured by Dow Corning Corp.) were mixed at a weight ratio of 9:1, and vapor was removed. A semiconductor nanocrystal dispersed in chloroform (Cd based core-shell structure, Nanodot-HE-620, manufactured by Ecoflux) was added into the obtained polymer resin mixture and uniformly mixed. In this case, the semiconductor nanocrystal was added at 1 part by weight based on 100 parts by weight of the polymer resin.

Meanwhile, two sheets of glass fabric woven with glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then cured at 80° C. for 1 hour to prepare a semiconductor nanocrystal film. After the curing, the obtained semiconductor nanocrystal film was delaminated from the glass substrate.

### Example 3: Fabrication of Semiconductor Nanocrystal Film

Bisphenol A diacrylate (Miramer M244, Miwon Chemical Co., Ltd.) and trimethylolpropane triacrylate (Miramer M3150, Miwon Chemical Co., Ltd.) were mixed at weight ratio of 4:1 and added with a photoinitiator (Irgacure 184) at 3 parts by weight based on 100 parts by weight of the entire monomer. A semiconductor nanocrystal dispersed in chloroform (Cd based core-shell structure, Nanodot-HE-620, manufactured by Ecoflux) was added into the obtained monomer mixture and uniformly mixed. In this case, the semiconductor nanocrystal was added at 1 part by weight based on 100 parts by weight of the acryl monomer.

Meanwhile, two sheets of glass fabric woven with glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then irradiated with light having a wavelength of 365 nm for 3 minutes using an ultraviolet (UV) lamp to provide a semiconductor nanocrystal film. The obtained semiconductor nanocrystal film was then delaminated from the glass substrate.

### Example 4: Fabrication of Semiconductor Nanocrystal Film

As a photoinitiator, 1 part by weight of Irgacure 184 and 1 part by weight of D-1173d were added into 100 parts by weight of trimethylolpropane triacrylate (Miramer M3150, Miwon Chemical Co., Ltd.). A semiconductor nanocrystal dispersed in chloroform (Cd based core-shell structure, Nanodot-HE-620, manufactured by Ecoflux) was added into the obtained monomer mixture and uniformly mixed. In this case, the semiconductor nanocrystal was added at 1 part by weight based on 100 parts by weight of the acryl monomer.

Meanwhile, two sheets of glass fabric woven with glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then heated at 60° C. for 5 hours and irradiated with light having a wavelength of 365 nm for 3 minutes using an ultraviolet (UV) lamp to provide a semiconductor nanocrystal film. After the curing, the obtained semiconductor nanocrystal film was delaminated from the glass substrate.

### Example 5: Fabrication of Semiconductor Nanocrystal Film

A semiconductor nanocrystal dispersed in chloroform (Cd based core-shell structure, Nanodot-HE-620, manufactured by Ecoflux) was added into an epoxy resin (E-30CL, manufactured by Loctite) and uniformly mixed for 1 hour. In this case, the semiconductor nanocrystal was added at 1 part by weight based on 100 parts by weight of the polymer resin.

Meanwhile, two sheets of glass fabric woven with glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then cured at 60° C. for 1 hour to prepare a semiconductor nanocrystal film. After the curing, the obtained semiconductor nanocrystal film was delaminated from the glass substrate.

### Example 6: Fabrication of Semiconductor Nanocrystal Film

A semiconductor nanocrystal dispersed in chloroform (Cd based core-shell structure, Nanodot-HE-620, manufactured by Ecoflux) was added into an epoxy silicone resin (manufactured by Solip Tech Co. Korea) and uniformly mixed. In this case, the semiconductor nanocrystal was added at 1 part by weight based on 100 parts by weight of the polymer resin.

Meanwhile, two sheets of glass fabric woven with glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then cured by ultraviolet (UV) light to provide a semiconductor nanocrystal film. After the curing, the obtained semiconductor nanocrystal film was delaminated from the glass substrate.

### Example 7: Fabrication of Semiconductor Nanocrystal Film

20 parts by weight of 3,4-epoxycyclohexylmethyl 3,4-epoxycyclohexanecarboxylate was mixed with 100 parts by weight of epoxy siloxane resin (manufactured by Solip Tech Co. Korea). A semiconductor nanocrystal dispersed in chloroform (Cd based core-shell structure, Nanodot-HE-620, manufactured by Ecoflux) was added into the obtained polymer resin mixture and uniformly mixed. In this case, the semiconductor nanocrystal was added at 1 part by weight based on 100 parts by weight of polymer resin.

Meanwhile, two sheets of glass fabric woven with glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then cured by ultraviolet (UV) light to provide a semiconductor nanocrystal film. After the curing, the obtained semiconductor nanocrystal film was delaminated from the glass substrate.

### Example 8: Fabrication of Semiconductor Nanocrystal Film

40 parts by weight of 3,4-epoxycyclohexylmethyl 3,4-epoxycyclohexanecarboxylate was mixed with 100 parts by weight of epoxy siloxane resin (manufactured by Solip Tech Co. Korea). A semiconductor nanocrystal dispersed in chloroform (Cd based core-shell structure, Nanodot-HE-620, manufactured by Ecoflux) was added into the obtained polymer resin mixture and uniformly mixed. In this case, the semiconductor nanocrystal was added at 1 part by weight based on 100 parts by weight of polymer resin.

Meanwhile, two sheets of glass fabric woven with glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then cured by ultraviolet (UV) light to provide a semiconductor nanocrystal film. After the curing, the obtained semiconductor nanocrystal film was delaminated from the glass substrate.

### Example 9: Fabrication of Semiconductor Nanocrystal Film

60 parts by weight of 3,4-epoxycyclohexylmethyl 3,4-epoxycyclohexanecarboxylate was mixed with 100 parts by weight of an epoxy siloxane resin (manufactured by Solip Tech Co. Korea). A semiconductor nanocrystal dispersed in chloroform (Cd based core-shell structure, Nanodot-HE-620, manufactured by Ecoflux) was added into the obtained polymer resin mixture and uniformly mixed. In this case, the semiconductor nanocrystal was added at 1 part by weight based on 100 parts by weight of the polymer resin.

Meanwhile, two sheets of glass fabric woven with glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then cured by ultraviolet (UV) light to provide a semiconductor nanocrystal film. After the curing, the obtained semiconductor nanocrystal film was delaminated from the glass substrate.

### Example 10: Fabrication of Semiconductor Nanocrystal Film

80 parts by weight of 3,4-epoxycyclohexylmethyl 3,4-epoxycyclohexanecarboxylate was mixed with 100 parts by weight of an epoxy siloxane resin (manufactured by Solip Tech Co. Korea). A semiconductor nanocrystal dispersed in chloroform (Cd based core-shell structure, Nanodot-HE-620, manufactured by Ecoflux) was added into the obtained polymer resin mixture and uniformly mixed. In this case, the semiconductor nanocrystal was added at 1 part by weight based on 100 parts by weight of the polymer resin.

Meanwhile, two sheets of glass fabric woven with glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then cured by ultraviolet (UV) light to provide a semiconductor nanocrystal film. After the curing, the obtained semiconductor nanocrystal film was delaminated from the glass substrate.

### Example 11: Fabrication of Semiconductor Nanocrystal Film

100 parts by weight of 3,4-epoxycyclohexylmethyl 3,4-epoxycyclohexanecarboxylate was mixed with 100 parts by weight of an epoxy siloxane resin (manufactured by Solip Tech Co. Korea). A semiconductor nanocrystal dispersed in chloroform (Cd based core-shell structure, Nanodot-HE-620, manufactured by Ecoflux) was added into the obtained polymer resin mixture and uniformly mixed. In this case, the semiconductor nanocrystal was added at 1 part by weight based on 100 parts by weight of the polymer resin.

Meanwhile, two sheets of glass fabric made of glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then cured by ultraviolet (UV) light to provide a semiconductor nanocrystal film. After the curing, the obtained semiconductor nanocrystal film was delaminated from the glass substrate.

### Example 12: Fabrication of Semiconductor Nanocrystal Film

30 parts by weight of 3,4-epoxycyclohexylmethyl 3,4-epoxycyclohexanecarboxylate was mixed with 100 parts by weight of a highly refractive epoxy siloxane resin (manufactured by Solip Tech Co. Korea). A semiconductor nanocrystal dispersed in chloroform (Cd based core-shell structure, Nanodot-HE-620, manufactured by Ecoflux) was added into the obtained polymer resin mixture and uniformly mixed. In this case, the semiconductor nanocrystal was added at 1 part by weight based on 100 parts by weight of the polymer resin.

Meanwhile, two sheets of glass fabric woven with glass fiber (E-glass, manufactured by Nittobo) were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then cured by ultraviolet (UV) light to provide a semiconductor nanocrystal film. After the curing, the obtained semiconductor nanocrystal film was delaminated from the glass substrate.

### Example 13: Fabrication of Semiconductor Nanocrystal Film

100 parts by weight of 3,4-epoxycyclohexylmethyl 3,4-epoxycyclohexanecarboxylate was mixed with 100 parts by weight of an epoxy siloxane resin (manufactured by Solip Tech Co. Korea). A semiconductor nanocrystal dispersed in chloroform (Cd based core-shell structure, Nanodot-HE-620, manufactured by Ecoflux) and a glass non-woven fabric made of glass fiber (E-CR glass; manufactured by Owens Corning) were added into the obtained polymer resin mixture and mixed. In this case, the semiconductor nanocrystal was added at 1 part by weight based on 100 parts by weight of the polymer resin. Subsequently, the preliminarily prepared polymer resin mixture in which the semiconductor nanocrystal and the glass non-woven fabric were added was spread on a glass substrate and cured by ultraviolet (UV) light to provide a semiconductor nanocrystal film. After the curing, the obtained semiconductor nanocrystal film was delaminated from the glass substrate.

### Example 14: Fabrication of Semiconductor Nanocrystal Film

100 parts by weight of 3,4-epoxycyclohexylmethyl 3,4-epoxycyclohexanecarboxylate was mixed with 100 parts by weight of an epoxy siloxane resin (manufactured by Solip Tech Co. Korea). A semiconductor nanocrystal dispersed in chloroform (Cd based core-shell structure, Nanodot-HE-620, manufactured by Ecoflux) was added into the obtained polymer resin mixture and uniformly mixed. In this case, the semiconductor nanocrystal was added at 1 part by weight based on 100 parts by weight of the polymer resin.

Meanwhile, aluminum was deposited at a thickness of 10 nm on glass fiber (E-glass, manufactured by Nittobo) to provide a metal layer on the glass fiber, and two sheets of glass fabric woven with glass fiber were prepared, and the two sheets of glass fabric were overlapped and disposed on a glass substrate. Subsequently, the preliminarily prepared polymer resin mixture in which the semiconductor nanocrystal was dispersed was poured into the two sheets of glass fabric to impregnate the polymer resin mixture in the two sheets of glass fabric. It was then cured by ultraviolet (UV) light to provide a semiconductor nanocrystal film. After the curing, the obtained semiconductor nanocrystal film was delaminated from the glass substrate.

### Comparative Example 1: Fabrication of Semiconductor Nanocrystal Film

100 parts by weight of 3,4-epoxycyclohexylmethyl 3,4-epoxycyclohexanecarboxylate was mixed with 100 parts by weight of epoxy siloxane resin (manufactured by Solip Tech Co. Korea). A semiconductor nanocrystal dispersed in chloroform (Cd based core-shell structure, Nanodot-HE-620, manufactured by Ecoflux) was added into the obtained polymer resin mixture and uniformly mixed. In this case, the semiconductor nanocrystal was added at 1 part by weight based on 100 parts by weight of the polymer resin.

Subsequently, the preliminarily prepared polymer resin mixture in which the semiconductor nanocrystal was dispersed was coated on a glass substrate and cured by ultraviolet (UV) light to provide a semiconductor nanocrystal film. After the curing, the obtained semiconductor nanocrystal film was delaminated from the glass substrate.

### Experimental Example 1: Measurement of Haze of Semiconductor Nanocrystal Film

A refractive index difference between the polymer matrix and the glass cloth of the obtained semiconductor nanocrystal film and haze of the semiconductor nanocrystal film were measured, and the results are shown in Table 1. Specifically, the refractive index difference, which is a refractive index difference between the cured polymer matrix and the glass cloth at a wavelength of 632.8 nm, was measured using a prism coupler (manufactured by Metricon), and the haze was measured using a haze meter (manufactured by Nippon Denshoku Industry).

TABLE 1

| | Refractive index difference | Haze (%) |
|---|---|---|
| Example 1 | 0.0027 | 8.27 |
| Example 2 | 0.0300 | 70.21 |
| Example 3 | 0.0433 | 87.35 |
| Example 4 | 0.0080 | 19.26 |
| Example 5 | 0.0100 | 25.13 |
| Example 6 | 0.0324 | 70.25 |
| Example 7 | 0.0329 | 70.33 |
| Example 8 | 0.0334 | 71.50 |
| Example 9 | 0.0337 | 74.90 |
| Example 10 | 0.0341 | 76.83 |
| Example 11 | 0.0345 | 77.65 |
| Example 12 | 0.0004 | 3.27 |

Referring to Table 1, it is confirmed that the semiconductor nanocrystal film may have haze of greater than or equal to 25% when the refractive index difference between the polymer matrix and the glass cloth is greater than or equal to 0.01, and the semiconductor nanocrystal film may have haze of greater than or equal to 70% when the refractive index difference between the polymer matrix and the glass cloth is greater than or equal to 0.03.

### Experimental Example 2: Evaluation of Coefficient of Thermal Expansion and Mechanical Characteristics of Semiconductor Nanocrystal Film

The semiconductor nanocrystal films obtained from Examples 11 and 13 and Comparative Example 1 were measured to determine a coefficient of thermal expansion and a Young's modulus, and the results are shown in Table 2.

Specifically, the coefficient of thermal expansion was measured using a Thermomechanical analyzer (SS6100, manufactured by SII Co.) and the Young's modulus was measured using a universal testing machine (manufactured by Shimadzu).

TABLE 2

| | Coefficient of thermal expansion | Young's modulus |
|---|---|---|
| | (ppm/° C.) | (GPa) |
| Comparative | 183 | 2.1 |
| Example 1 | | |
| Example 11 | 15 | 5.3 |
| Example 13 | 17 | 5.1 |

Referring to Table 2, it is confirmed that the coefficient of thermal expansion was remarkably decreased and the Young's modulus was remarkably increased in Examples 11 and 13 using glass cloth, compared to those of Comparative Example 1. Thereby, in the semiconductor nanocrystal film according to one embodiment of the present invention, the film may not be significantly deformed even when the temperature thereof is increased due to heat or continuous exposure to light, or it receives external force or impact.

### Experimental Example 3: Evaluation of Haze Improvement by Metal Layer

The semiconductor nanocrystal films obtained from Examples 11 and 14 were measured for haze, and the results are shown in Table 3.

According to Example 14, a semiconductor nanocrystal film was obtained in accordance with the same procedure as in Example 11, except that a glass cloth coated with a metal layer was used.

The haze was measured using haze meter (manufactured by Nippon Denshoku Industry).

TABLE 3

| | Haze (%) |
|---|---|
| Example 11 | 77.65 |
| Example 14 | 81.65 |

Referring to Table 3, it is confirmed that the haze was increased when using the glass cloth coated with the metal layer. In addition, the glass cloth coated with the metal layer may fluently emit heat in the semiconductor nanocrystal film to the outside, so thermal stability of the semiconductor nanocrystal film may be remarkably improved.

Thereby, the semiconductor nanocrystal film according to one embodiment of the present invention has excellent thermal stability and mechanical characteristics such that it can be applicable to various fields, and particularly, there is less concern about damage even if exposed to light for a long time, so it is anticipated to be usable for a light source and the like.

While this invention has been described in connection with what is presently considered to be practical exemplary embodiments, it is to be understood that the invention is not limited to the disclosed embodiments, but on the contrary, is intended to cover various modifications and equivalent arrangements included within the spirit and scope of the appended claims.

### DESCRIPTION OF SYMBOLS

1: polymer matrix
2: semiconductor nanocrystal
3: glass cloth

What is claimed is:

1. A semiconductor nanocrystal film, comprising:
a glass cloth including a glass fiber having a composition of E glass, S glass, T glass, or E-CR glass,
a polymer matrix impregnated in the glass cloth, and
a semiconductor nanocrystal dispersed in the polymer matrix,
wherein the semiconductor nanocrystal film has a film shape, and the semiconductor nanocrystal film has a coefficient of thermal expansion of less than or equal to 50 ppm/° C.

2. The semiconductor nanocrystal film of claim 1, wherein the polymer matrix includes a (meth)acryl-based resin, an epoxy-based resin, a urethane-based resin, a polyester-based resin, a silicone-based resin, a siloxane-based resin, or a combination thereof.

3. The semiconductor nanocrystal film of claim 1, wherein the glass cloth is a glass woven fabric, a glass non-woven fabric, or a mixture thereof.

4. The semiconductor nanocrystal film of claim 1, wherein the glass cloth further includes a metal layer formed on the surface thereof.

5. The semiconductor nanocrystal film of claim 1, wherein a refractive index difference between the polymer matrix and the glass cloth at a wavelength of 632.8 nm is greater than or equal to 0.01.

6. The semiconductor nanocrystal film of claim 1, wherein the semiconductor nanocrystal is selected from a Group II-VI compound, a Group II-V compound, a Group III-VI compound, a Group III-V compound, a Group IV-VI compound, a Group II-III-VI compound, a Group II-IV-VI compound, a Group II-IV-V compound, a Group IV compound, an alloy thereof, and a combination thereof.

7. The semiconductor nanocrystal film of claim 1, wherein the semiconductor nanocrystal film is employed for a color conversion device of a photoelectric device, a display, or a light.
